(19) United States
(12) Patent Application Publication
(10) Pub. No.: US 2006/0260840 A1
(43) Pub. Date: Nov. 23, 2006

(54) Outer case of electronic device

(76) Inventor: Inhan Kim, Yongin-si (KR)

Correspondence Address: CHRISTIE, PARKER & HALE, LLP, PO BOX 7068, PASADENA, CA, 91109-7068, US

(21) Appl. No.: 11/410,505

(22) Filed: Apr. 24, 2006

(30) Foreign Application Priority Data
Apr. 26, 2005 (KR) 10-2005-0034747

(51) Int. Cl. H05K 9/00

(52) U.S. Cl. 174/377

(57) ABSTRACT

An outer case of an electronic device includes a case which contains an electronic element; and a ceramic-containing outer layer or a polyurethane outer layer which covers at least a portion of a surface of the case.

### CROSS-REFERENCE TO RELATED PATENT APPLICATION

This application claims priority to and the benefit of Korean Patent Application No. 10-2005-0034747, filed on Apr. 26, 2005, in the Korean Intellectual Property Office, the entire content of which is incorporated herein by reference.

### BACKGROUND OF THE INVENTION

As a typical case for protecting electronic elements contained inside electronic devices, a stainless steel material having a good rigidity is used. The outer surface of the case made of the stainless steel material is subject to a corrosion treatment to facilitate plating, and then chromium is plated thereon.

Chromium is produced mainly in a chromium mine, and is a silver-white metal having an excellent thermal resistance. Further, chromium is widely used as a plating material because it has good corrosion resistance. A nichrome wire is widely used as an electric heating wire and is a ferrous alloy having excellent thermal resistance, good electric resistance, and good corrosion resistance.

An industrially used chromium compound includes chromium 3+ ion and chromium 6+ ion. A chromic acid including chromium 6+ ion or a bichromic acid is harmful to the human body, and is produced due to corrosion and oxidation.

If chromic acid or bichromic acid contacts skins or mucous membranes, burns may occur. Further, inflammations and respiratory ailments may be caused by dust or vapor. In particular, chromic acid is a strong acid and is highly oxidative, which may erode other metals, drapers, or leathers.

### SUMMARY

An outer case of an electronic device includes a case which contains an electronic element; and a ceramic-containing outer layer which covers at least a portion of a surface of the case. In one embodiment, the ceramic-containing outer layer is made of a paint layer including a ceramic pigment. The ceramic pigment may be nontoxic or an oxidized steel. The ceramic pigment may be CaTaO2N or CaTaON2 having a Perovskite structure.

In one embodiment, the case is made of steel, stainless steel, or aluminum, and at least a portion of the surface of the case is etched. A roughness of the at least a portion of the surface of the case may be 0.2˜0.7 μm in depth. The case may be a secondary battery case.

In one embodiment, the ceramic-containing outer layer includes a ceramic pigment and a polyurethane resin, and in another embodiment, the ceramic-containing outer layer is a ceramic sinter layer.

In another embodiment, an outer case of an electronic device includes a case which contains an electronic element; and a polyurethane outer layer which covers at least a portion of a surface of the case. The polyurethane outer layer may be a foamable outer layer, and the case may be made of steel, stainless steel, or aluminum. In one embodiment, the at least a portion of the surface of the case is etched, and a roughness of the at least a portion of the surface of the case is 0.2˜0.7 μm in depth. The case may be a secondary battery case.

### BRIEF DESCRIPTION OF THE DRAWINGS

The above and other features and aspects of the present invention will become more apparent by describing in detail exemplary embodiments thereof with reference to the attached drawings in which:

FIG. 1 is a partial sectional view of an outer case of an electronic device according to an embodiment of the present invention; and

FIG. 2 is an exploded perspective view illustrating an example using an outer case of an electronic device according to an embodiment of the present invention.

### DETAILED DESCRIPTION

Hereinafter, the present invention will be described in detail by explaining exemplary embodiments of the invention with reference to the attached drawings.

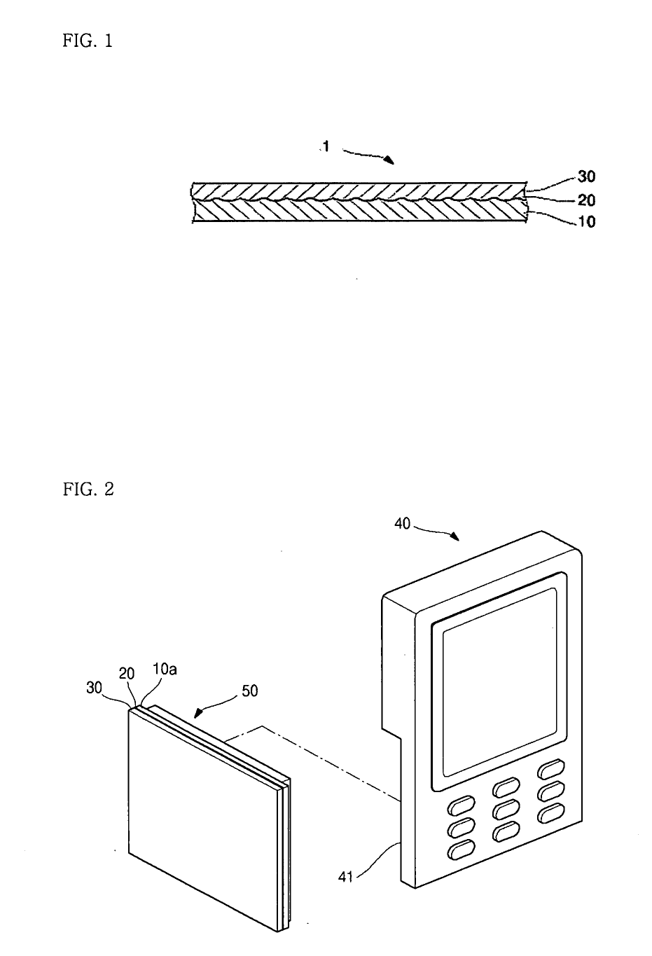

FIG. 1 is a partial sectional view of an outer case of an electronic device according to an embodiment of the present invention. FIG. 2 is a view illustrating an example using an outer case of an electronic device according to an embodiment of the present invention.

Referring to FIGS. 1 and 2, an electronic device 40 includes an outer case 1 having a case 10 containing a specific electronic element and an outer layer 30 covering an outermost surface of the case 10.

The case 10 may be made of steel, stainless steel, or aluminum material which has a specific rigidity suitable for protecting electronic elements contained in the electronic device.

The outer layer 30 is made of ceramic-containing material. Ceramic is a nonmetal inorganic solid material that is produced through a heat treatment at a high temperature, and has excellent fire resistance. The ceramic-containing material may be made of a paint-type material. Here, the paint-type ceramic outer layer 30 may be coated or sprayed on an outer surface of the case 10.

Further, the outer layer 30 may be made of a polyurethane material. An alcoholic hydroxy group (—OH) is bonded with an isocyanic acid group (—NCO) so as to form the polyurethane material. The polyurethane material has excellent wear resistance and elasticity.

The polyurethane material may be sprayed on the outer surface of the case 10 so as to form the outer layer 30. The polyurethane material may be foamable.

The outer surface of the case 10, in these embodiments, has a specific roughness in order to increase a bonding force with respect to the outer layer 30 formed at the outermost surface. Thus, a rough surface 20 having a specific roughness is formed on the case 10 by etching. The roughness of the rough surface 20 may be 0.2˜0.7 μm deep.

The process in which a portable communication device or other portable electronic device uses an outer case of an electronic device according to an embodiment of the present invention will now be described.

First, an outer surface of the case 10, which is made of steel, stainless steel, or aluminum and is used in a portable communication device, is etched by using chemicals such as nitric acid (NHO₃) and chromate (CrO₃). The rough surface 20 having a roughness about 0.2˜0.7 μm in depth is formed on the etched case 10.

A battery connector 41 is positioned at one side of the electronic device 40 to allow portability of a battery. When a battery 50 is included in the electronic device 40, the case 10 can include a battery bracket 10a. The battery bracket 10a may be made of the same material as the case 10. The battery 50 connects to the battery connector 41, so that the battery including the battery bracket 10a, as a part of a battery case and the outer layer 30 forms a flush surface with the outer case of the electronic device 40.

The rough surface 20 created by etching is formed on the case 10 that is connected to the battery connector 41, and the rough surface 20 and the case 10 form a flush surface with the housing of the electronic device 40.

The case 10, of which the outer surface is etched to form the rough surface 20 about 0.2˜0.7 μm, and the battery bracket 10a are cleansed to remove chemicals remaining in the case 10 and the battery bracket 10a.

Next, a ceramic-containing paint is sprayed or coated on the rough surface 20 of the case 10, thereby forming the outer layer 30.

The ceramic-containing paint may be made of a ceramic pigment and resin. The ceramic pigment may be an oxidized steel pigment that is a nontoxic ceramic pigment, or CaTaO₂N (or CaTaON₂) having a Perovskite structure.

On the rough surface 20 of the case 10 or the battery bracket 10a, a polyurethane material without a pigment component or a polyurethane resin with a pigment component may be foamed, or a ceramic material may be sintered to form the outer layer 30. In one embodiment, the case 10 is a secondary battery case.

When an electronic element is contained in the electronic device 40, and the battery 50 is connected to the battery connector 41, the outer surface of the electronic device 40 is covered by ceramic or polyurethane.

According to the above described embodiments of the present invention, an outer layer made of ceramic or polyurethane is formed on an outer case of an electronic device, thereby avoiding environmental regulations.

In addition, an exterior of the electronic device can be beautified due to various types and colors of ceramic.

In addition, since polyurethane has elasticity, an external impact imposed on the electronic device can be absorbed.

What is claimed is:

1. An outer case of an electronic device comprising:
a case which contains an electronic element; and
a ceramic-containing outer layer which covers at least a portion of a surface of the case.

2. The outer case of an electronic device according to claim 1, wherein the ceramic-containing outer layer is made of a paint layer including a ceramic pigment.

3. The outer case of an electronic device according to claim 2, wherein the ceramic pigment is nontoxic.

4. The outer case of an electronic device according to claim 3, wherein the ceramic pigment is an oxidized steel

5. The outer case of an electronic device according to claim 3, wherein the ceramic pigment is CaTaO₂N having a Perovskite structure.

6. The outer case of an electronic device according to claim 3, wherein the ceramic pigment is CaTaON₂ having a Perovskite structure.

7. The outer case of an electronic device according to claim 1, wherein the case is made of steel, stainless steel, or aluminum.

8. The outer case of an electronic device according to claim 1, wherein the at least a portion of the surface of the case is etched.

9. The outer case of an electronic device according to claim 8, wherein a roughness of the at least a portion of the surface of the case is 0.2˜0.7 μm in depth.

10. The outer case of an electronic device according to claim 1, wherein the case is a secondary battery case.

11. The outer case of an electronic device according to claim 1, wherein the ceramic-containing outer layer includes a ceramic pigment and a polyurethane resin.

12. The outer case of an electronic device according to claim 1, wherein the ceramic-containing outer layer is a ceramic sinter layer.

13. An outer case of an electronic device comprising:
a case which contains an electronic element; and
a polyurethane outer layer which covers at least a portion of a surface of the case.

14. The outer case of an electronic device according to claim 13, wherein the polyurethane outer layer is a foamable outer layer.

15. The outer case of an electronic device according to claim 13, wherein the case is made of steel, stainless steel, or aluminum.

16. The outer case of an electronic device according to claim 13, wherein the at least a portion of the surface of the case is etched.

17. The outer case of an electronic device according to claim 16, wherein a roughness of the at least a portion of the surface of the case is 0.2˜0.7 μm in depth.

18. The outer case of an electronic device according to claim 13, wherein the case is a secondary battery case.
